(19) United States
(12) Patent Application Publication
(10) Pub. No.: US 2015/0206789 A1
(43) Pub. Date: Jul. 23, 2015

(54) METHOD OF MODIFYING POLYSILICON LAYER THROUGH NITROGEN INCORPORATION FOR ISOLATION STRUCTURE

(71) Applicant: NANYA TECHNOLOGY CORPORATION, TAO-YUAN HSIEN (TW)

(72) Inventors: JONATHAN PAPPAS, PERRYSBURG, OH (US); GIORGIO MARIOTTINI, BOISE, ID (US); DARWIN FAN, BOISE, ID (US); HSIAO TING WU, YILAN COUNTY (TW); CHENG SHUN CHEN, MIAOLI COUNTY (TW)

(73) Assignee: NANYA TECHNOLOGY CORPORATION, TAO-YUAN HSIEN (TW)

(21) Appl. No.: 14/157,855

(22) Filed: Jan. 17, 2014

(51) Int. Cl. H01L 21/762; H01L 21/02; H01L 27/146; H01L 21/311; H01L 21/3105

(52) U.S. Cl. CPC H01L 21/76229; H01L 21/31111; H01L 21/31144; H01L 21/31053; H01L 27/1463; H01L 21/02247; H01L 21/02252; H01L 21/02255

(57) ABSTRACT

The present disclosure relates to a method of modifying a polysilicon layer, which includes the following steps. A polysilicon layer is provided. Nitrogen is incorporated into the polysilicon layer toward a predetermined depth. The polysilicon layer incorporated with nitrogen is etched, wherein after the nitrogenized polysilicon is removed, the formation of the remaining polysilicon layer is nearly indistinguishable from the formation of the polysilicon layer.

### BACKGROUND

1. Technical Field

The present disclosure generally relates to a method of modifying a polysilicon layer. More particularly, the present disclosure relates to a method of modifying a polysilicon layer through nitrogen incorporation.

2. Background

In semiconductor technologies, image sensors are used for sensing a volume of exposed light projected towards the semiconductor substrate. Both CMOS image sensors and CCD image sensors are widely used in various applications such as digital cameras. These image sensors use an array of pixels that include light sensitive elements to collect photo energy to convert images into digital data. However, as pixels are scaled down, the sensitivity of a pixel tends to decrease. In addition, there is increased crosstalk between pixels. Crosstalk may degrade the spatial resolution, reduce overall sensitivity, provide for poor color separation, and may lead to additional noise in the image, in particular, after a color correction procedure. Processes including those requiring thinner layers of material (e.g. thin dielectric and metal layers) and thin color filters may be utilized to improve the optical crosstalk. However, these conventional methods of improving electrical crosstalk, such as providing a sensor with a thin epitaxial layer, provide for additional issues such as electrostatic discharge (ESD) failures. Further issues with conventional image sensors include long wavelength light sensitivity and image defects, such as those occurring from blooming effects (e.g. certain areas of the output image appearing brighter than the original image.) In addition, the thin epitaxial layer may induce polysilicon bump defects, which would influence the above-mentioned issues.

The present disclosure is directed to various methods that may solve, or at least reduce, some or all of the aforementioned problems.

### SUMMARY

In order to improve the above-identified defects, the present disclosure provides a method of modifying a polysilicon layer and a method of fabricating an isolation structure for an image sensor device.

The method of modifying a polysilicon layer in the present disclosure comprises the following steps: incorporating nitrogen into the polysilicon layer toward a first depth; and performing an etching process to remove the first nitrogenized polysilicon portion, wherein the polysilicon layer is not etched by the etching process.

The nitrogen incorporating step in the present disclosure is performed by a process selected from a decoupled plasma nitridization, an ammonia anneal, and a nitrous oxide (N₂O) plasma treatment.

The etching step in the present disclosure is performed by using a phosphoric acid/peroxide mixture (Hot Phos).

The etching step in the present disclosure is performed by using hydrogen fluoride (HF) in deionized water.

The method of modifying a polysilicon layer in the present disclosure further comprises a step of forming a photoresist masking layer on the polysilicon layer.

The method of modifying a polysilicon layer in the present disclosure further comprises a step of incorporating nitrogen into the photoresist masking layer and the polysilicon layer toward a second depth to form a second nitrogenized polysilicon portion.

The method of modifying a polysilicon layer in the present disclosure further comprises a step of removing the photoresist masking layer.

The method of modifying a polysilicon layer in the present disclosure further comprises a step of performing a second etching process to remove the second nitrogenized polysilicon portion, wherein the polysilicon layer is not etched by the second etching process.

The method of fabricating an isolation structure for an image sensor device in the present disclosure comprises the following steps: providing a substrate having a pixel region and a peripheral region; forming a photoresist masking layer with a predetermined pattern on the substrate; forming a plurality of trenches in the pixel region in accordance with the predetermined pattern, wherein the trenches have a first depth; forming at least one groove in the peripheral region in accordance with the predetermined pattern, wherein the at least one groove has a second depth; incorporating nitrogen into the substrate at the bottom of the trenches and at the bottom of the at least one groove to form a nitrogenized portion; performing an etching process to remove the nitrogenized portion, wherein the substrate is not etched by the etching process; removing the photoresist masking layer; depositing a layer of an insulating material on the substrate; and planarizing the layer of the insulation material.

Another function of the present disclosure will be described in the following paragraphs. Certain functions can be realized in the present section, while the other functions can be realized in the detailed description. In addition, the indicated components and the assembly of such can be explained and achieved by the details of the present disclosure. Notably, the previous explanation and the following description are demonstrated so as not to limit the scope of the present disclosure.

The foregoing has outlined rather broadly the features and technical benefits of the disclosure in order that the detailed description of the disclosure that follows may be better understood. Additional features and benefits of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the disclosure. It should also be realized by those skilled in the art that such equivalent constructions do not depart from the spirit and scope of the disclosure as set forth in the appended claims.

### BRIEF DESCRIPTION OF THE DRAWINGS

The accompanying drawings, which are incorporated in and constitute a part of this specification, illustrate embodiments of the disclosure and, together with the description, serve to explain the principles of the disclosure.

The foregoing summary, as well as the following detailed description of the disclosure, will be better understood when read in conjunction with the appended drawings. For the purpose of illustrating the disclosure, there are examples shown in the drawings which are presently preferred. However, it should be understood that the disclosure is not limited to the precise arrangements and instrumentalities that are shown.

A more complete understanding of the present disclosure may be derived by referring to the detailed description and claims when considered in connection with the Figures, where like reference numbers refer to similar elements throughout the Figures, and:

FIG. 1 is a flow chart of a method of modifying a polysilicon layer through nitrogen incorporation in accordance with an embodiment of the present disclosure;

FIG. 2 is a schematic view of a structure having a substrate and a thick photoresist layer in accordance with the embodiment of the present disclosure;

FIG. 3 is a schematic view of a nitrogen incorporating method in accordance with an embodiment of the present disclosure;

FIG. 4 is a schematic view of the removal of the thick photoresist layer in accordance with an embodiment of the present disclosure;

FIG. 5 is a schematic view of a the removal of the nitrogenized polysilicon portion in accordance with an embodiment of the present disclosure;

FIG. 6 is a schematic view of the nitrogen incorporation process in accordance with another embodiment of the present disclosure;

FIG. 7 is a schematic view of the height difference between the surface area and another surface area in accordance with another embodiment of the present disclosure;

FIG. 8 is a flow chart of the method of fabricating an isolation structure for an image sensor device in accordance with another embodiment of the present disclosure;

FIG. 9 is a cross-sectional view of the substrate having a pixel region and a peripheral region in accordance with the embodiment of the present disclosure;

FIG. 10 illustrates a schematic view of a predetermined pattern of a photoresist masking layer formed on the substrate in accordance with the embodiment of the present disclosure;

FIG. 11 illustrates a schematic view of trenches etched in the epi layer of the substrate in accordance with the embodiment of the present disclosure;

FIG. 12 illustrates a schematic view of nitrogen incorporation at the bottom of the trenches in accordance with the embodiment of the present disclosure;

FIG. 13 illustrates a schematic view of the removal of the nitrogenized portion in accordance with the embodiment of the present disclosure;

FIG. 14 illustrates a schematic view of the removal of the photoresist masking layer in accordance with the embodiment of the present disclosure;

FIG. 15 illustrates a schematic view of the deposition of the insulating material in accordance with the embodiment of the present disclosure; and

FIG. 16 illustrates a schematic view of the planation of the insulating layer in accordance with the embodiment of the present disclosure.

### DETAILED DESCRIPTION

The present disclosure is directed to a method of modifying a polysilicon layer and a method of fabricating an isolation structure for an image sensor device. In order to make the present disclosure completely comprehensible, detailed steps and structures are provided in the following description. Obviously, implementation of the present disclosure does not limit special details known by persons skilled in the art. In addition, known structures and steps are not described in details, so as not to limit the present disclosure unnecessarily. Preferred embodiments of the present disclosure will be described below in detail. However, in addition to the detailed description, the present disclosure may also be widely implemented in other embodiments. The scope of the present disclosure is not limited to the detailed embodiments, and is defined by the claims.

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In addition, unless specifically stated otherwise, as apparent from claims and detailed description, it is appreciated that throughout the specification the quantity of components is single. If the quantity of the labeled component is one, the quantifier is explained to include one unit or at least one unit. If the quantity of the labeled component is plurality, the quantifier is explained to include at least two units.

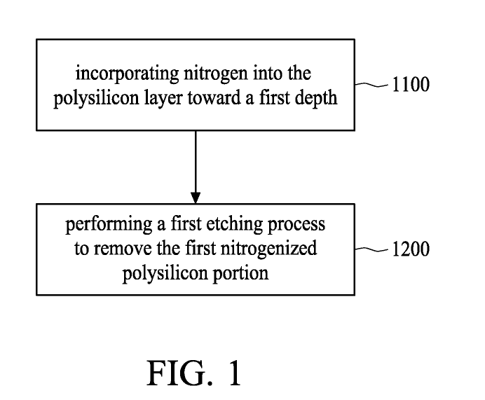

As shown in FIG. 1, the present disclosure provides the method of modifying a polysilicon layer through nitrogen incorporation. The method includes the following steps. In step 1100, nitrogen is incorporated into the polysilicon layer toward a first depth to form a first nitrogenized polysilicon potion. In step 1200, a first etching process is performed to remove the first nitrogenized polysilicon portion, wherein the polysilicon layer is not etched by the first etching process.

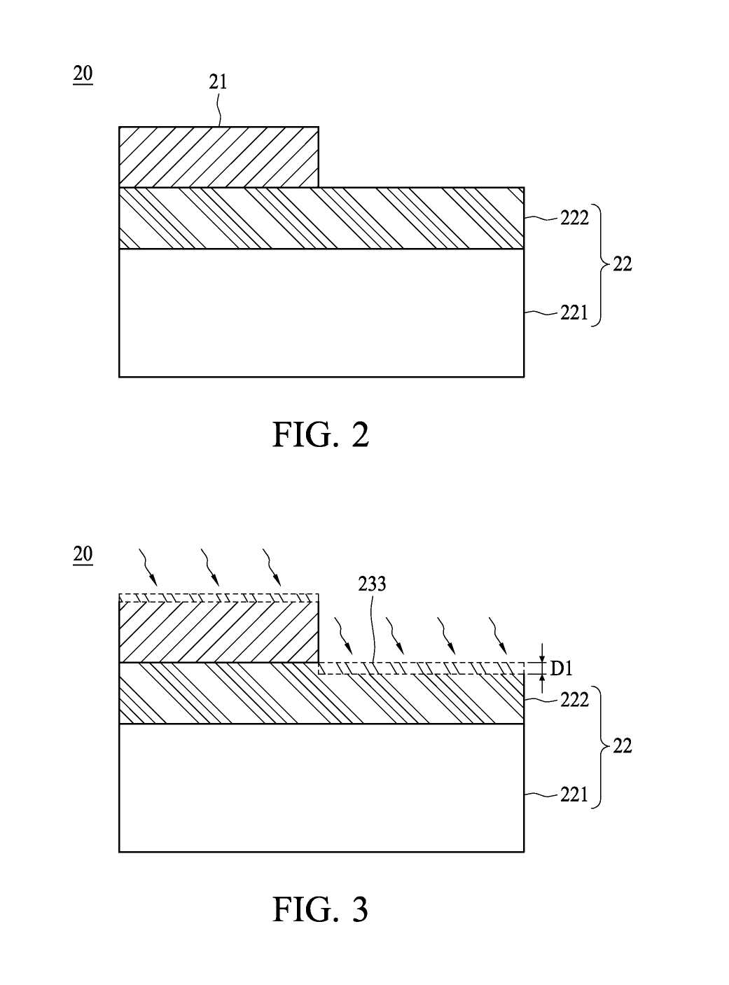

FIGS. 2 through 5 are cross-sectional views illustrating the foregoing method of modifying a polysilicon layer through nitrogen incorporation in accordance with one embodiment of the present disclosure. It should be understood that the description of the various aspects of the present disclosure are merely illustrative and that they should not be taken in a limiting sense.

Referring to FIG. 2, a structure 20 has a substrate 22 including a bottom layer 221 and a polysilicon layer 222 and a thick photoresist layer 21 disposed over the polysilicon layer 222. However, in another embodiment (not shown), the bottom layer 221 can be ignored.

Referring to FIG. 3, the structure 20 is treated by the nitrogen incorporating process, which is, but not limited to be, selected from a decoupled plasma nitridization, an ammonia anneal, and a nitrous oxide (N₂O) plasma treatment. In the embodiment, the structure 20 is implemented through a decoupled plasma nitridization (DPN) to form a first nitrogenized polysilicon portion 223 with a first depth.

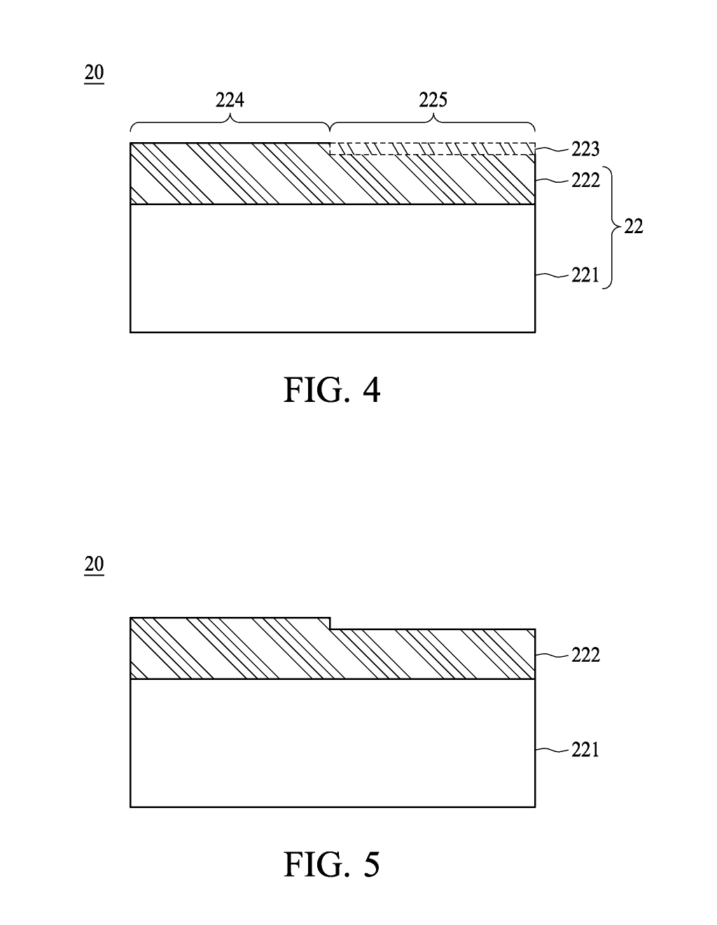

Referring to FIG. 4, the thick photoresist layer 21 is removed from the structure 20. Thus, the polysilicon layer 222 has two surface areas 224 and 225. The composition of the surface area 224 is the same as that of the polysilicon layer 222. Since the surface area 225 of the polysilicon layer 222 is incorporated with nitrogen to form the nitrogenized polysilicon portion 223, the composition of the surface area 225 is distinguishable from the composition of the surface area 224.

The structure 20 can be processed in a number of ways. The nitrogenized polysilicon portion 223 may just be used as a passivation film for the polysilicon layer 222 or be etched by a wet chemical process, such as hot phosphoric acid and peroxide (also known as Hot Phos). However, the wet chemical process is not limited to the Hot Phos process, and can otherwise be etched by hydrogen fluoride (HF) in deionized water for removal of nitrogen rich polysilicon portion 223 to form a structure 20 shown in FIG. 5. Referring to FIG. 5, the polysilicon layer 222 is not etched by the first etching process.

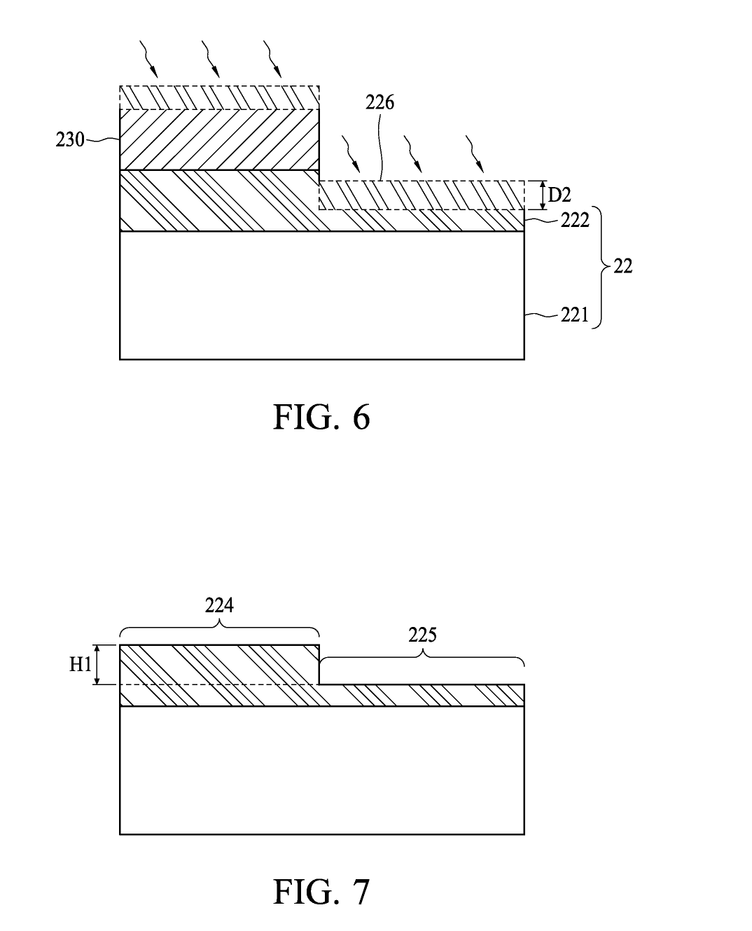

After forming another photoresist masking layer 230 is formed on the polysilicon layer 222, in another embodiment shown in FIGS. 6 and 7, the nitrogen incorporation process can be repeated or treat on the photoresist masking layer 230 and the polysilicon layer 222 to reach a second depth D1 to form a second nitrogenized polysilicon portion 226.

After the photoresist masking layer 230 is removed, a second etching process is performed to remove the second nitrogenized polysilicon portion 226, wherein the polysilicon layer 222 is not etched by the second etching process to form a structure shown in FIG. 7. In addition, the second etching process may be similar with the first etching process. Thus, the second depth D1 shown in FIG. 6 may be adjusted in accordance with various designs so as to adjust the height difference H1 between the surface area 224 and the surface area 225.

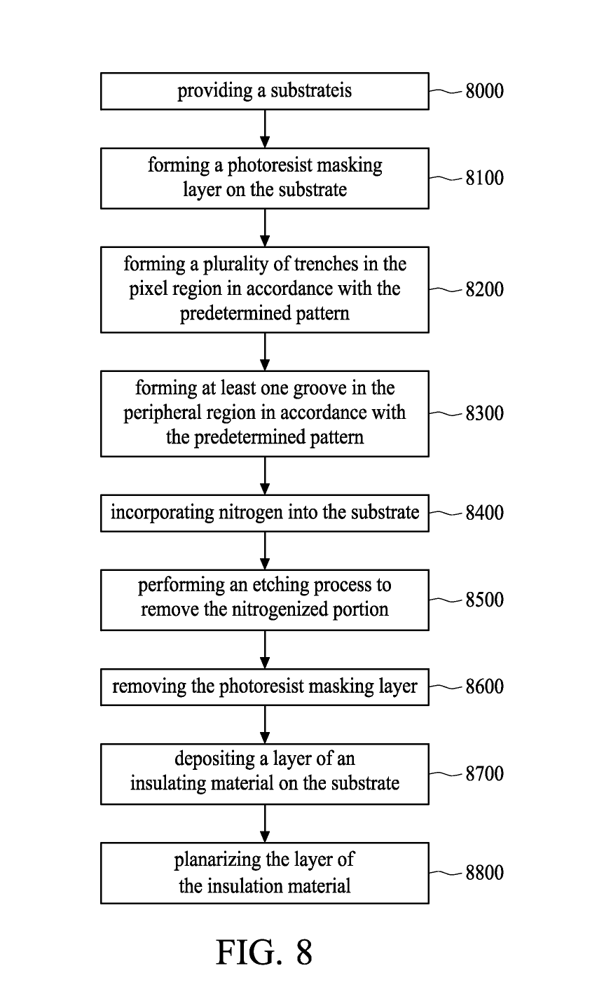

As shown in FIG. 8, the present disclosure provides the method of fabricating an isolation structure for an image sensor device. The method includes the following steps. In step 8000, a substrate having a pixel region and a peripheral region is provided. In step 8100, a photoresist masking layer with a predetermined pattern is formed on the substrate. In step 8200, a plurality of trenches in the pixel region is formed in accordance with the predetermined pattern, wherein the trenches have a first depth. In step 8300, at least one groove in the peripheral region is formed in accordance with the predetermined pattern, wherein the at least one groove has a second depth. In step 8400, nitrogen is incorporated into the substrate at the bottom of the trenches and at the bottom of the at least one groove to form a nitrogenized portion. In step 8500, an etching process is performed to remove the nitrogenized portion, wherein the substrate is not etched by the etching process. In step 8600, the photoresist masking layer is removed. In step 8700, a layer of an insulating material is deposited on the substrate. In step 8800, the layer of the insulation material is planarized.

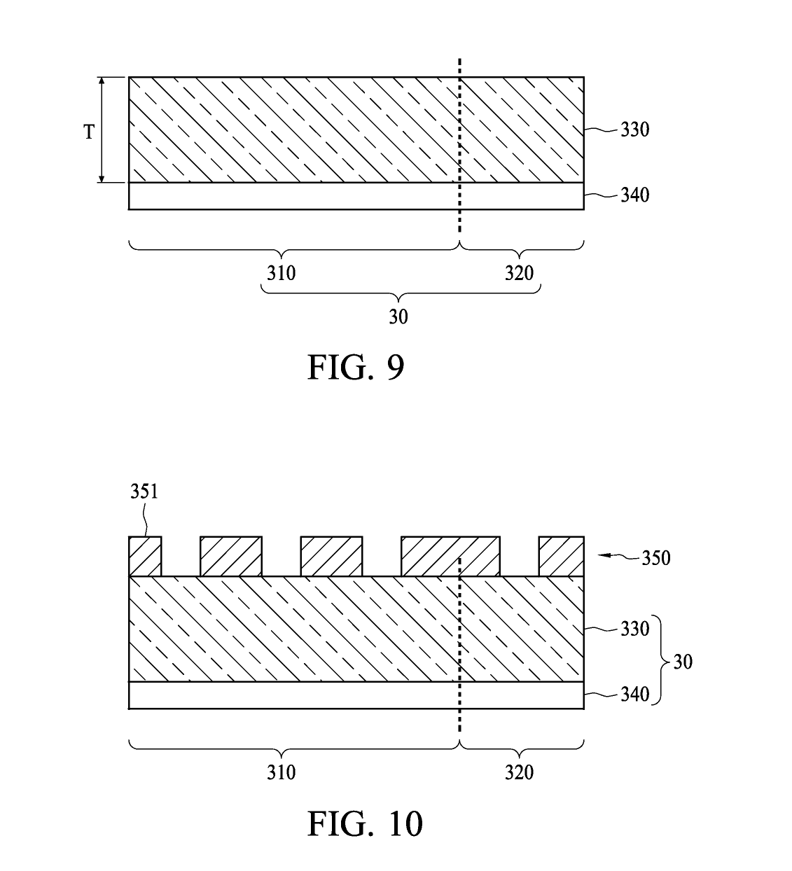

FIGS. 9 through 15 are cross-sectional views illustrating the foregoing method of fabricating the isolation structure for an image sensor device in accordance with one embodiment of the present disclosure. It should be understood that the description of the various aspects of the present disclosure are merely illustrative and that they should not be taken in a limiting sense.

Referring to FIG. 9, the method begins at step 8000 where a substrate 30 having a pixel region 310 and a peripheral region 320 is provided. The pixel region 310 includes an array of pixels (not shown). In the peripheral region 320, additional circuitry and inputs/outputs are provided adjacent to the pixel region 310 for providing an operation environment for the pixels and/or for supporting external communications with the pixels. The peripheral region 320 may also be known as a logic region as it may include logic circuitry associated with the pixels. The peripheral region 320 may include a low power logic circuit. The low-power logic circuit may include a low power, high-speed, high-performance logic circuit. The peripheral region 320 may include circuits for example, to drive the pixels in order, to obtain signal charges, A/D converters, processing circuits for forming image output signals, electrical connections operable for connecting to other devices, and/or other components known in the art. In another embodiment, the peripheral region 320 includes a MOSFET device having a source, drain, and gate electrode, all including a silicide layer. The silicide layer may include a silicide, such as nickel silicide, cobalt silicide, tungsten silicide, tantalum silicide, titanium silicide, platinum silicide, erbium silicide, palladium silicide, and/or combinations thereof.

The substrate 30 may be silicon in a crystalline structure or a polysilicon. In alternative embodiments, the substrate 30 may include other elementary semiconductors, such as germanium, or include a compound semiconductor, such as silicon carbide, gallium arsenide, indium arsenide, and indium phosphate. In an embodiment, the substrate 30 is a P-type substrate (P-type conductivity) (e.g. a substrate doped with P-type dopants, such as boron or aluminum, by conventional processes, such as diffusion or ion implantation). In other embodiments, the substrate 30 may include a P+ substrate, N+ substrate, and/or other conductivities known in the art. The substrate 10 may include a silicon on an insulator (SOI) substrate. The epi layer 330 allows for a different doping profile than other portions of the substrate 30, including the sub layer 340. The epi layer 330 may be grown on the substrate 30 using conventional methods. In an embodiment, the epi layer 330 is a P− epi layer. In an embodiment, the sub layer 340 is a P+ sub layer. Possible embodiments may include the epi layer 330 being an N− epi layer and the sub layer 340 being an N+ sub layer, the epi layer 330 being an N− epi layer and the sub layer 340 being a P+ sub layer, and/or other conductivities known in the art. The thickness T of the epi layer 330 may be between approximately 2 μm and 10 μm. In a further embodiment, the thickness T of the epi layer 330 may be approximately 4 μm.

In an embodiment, the epi layer 330 has a P-type conductivity and the photodiode included in the pixels (not shown) formed on the substrate 30 includes a photodetector with an N-type photogeneration region (e.g. an N-type well formed in a P− epitaxial layer). The N-type photogeneration region may be formed by doping the substrate with an N-type dopant, such as phosphorous, arsenic, and/or other N-type dopant known in the art. The doping may be accomplished by conventional processes known in the art, such as photolithography patterning followed by ion implantation or diffusion. In a further embodiment, the photodetector includes a pinned photodiode. The pinned layer may be doped with a P-type dopant. The P-type dopant may include boron, aluminum, and/or other dopants known in the art that provide P-type conductivity.

In the embodiment of FIG. 9, the substrate 30 is provided. The substrate 30 includes a sub layer 340 and an epi layer 330. In the embodiment, the sub layer 340 may be a wafer and the epi layer 330 may be a deposited polysilicon layer. In addition, the substrate 30 has the foresaid pixel region 310 and peripheral region 320.

The method then proceeds to step 8100 where a photoresist masking layer 351 with a predetermined pattern 350 is formed on the substrate 30 as shown in FIG. 10. In particular, the photoresist masking layer 351 is formed on the epi layer 330.

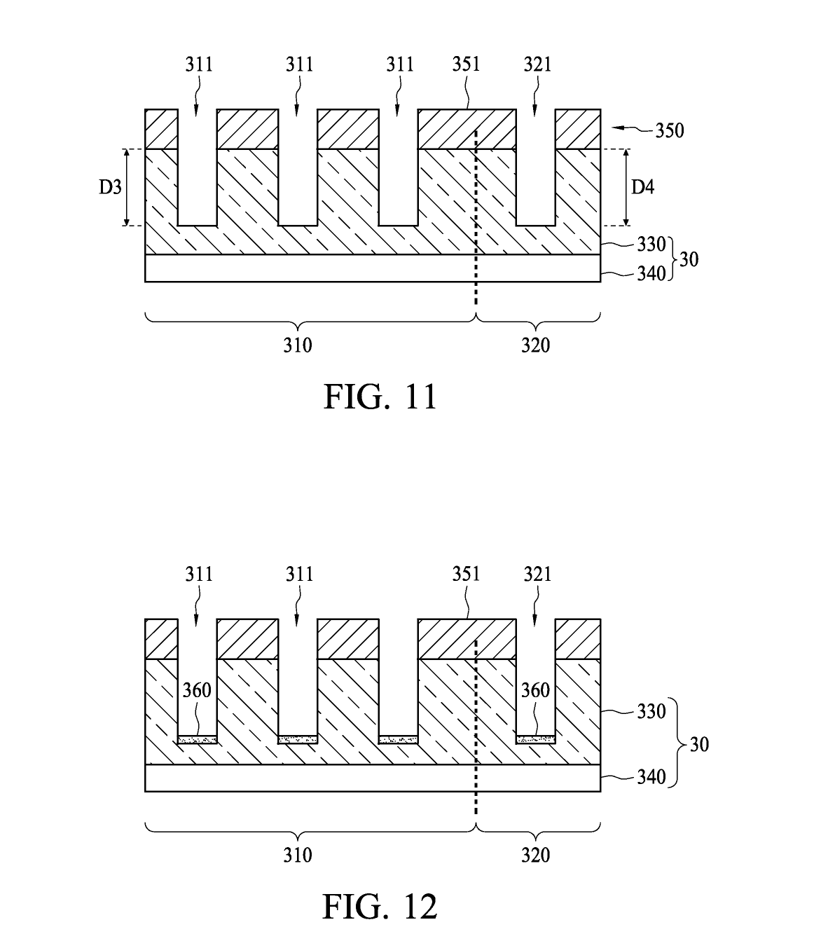

The method proceeds to step 8200 where a plurality of trenches 311 are formed in the pixel region 310 of the substrate 30 in accordance with the predetermined pattern 350 as shown in FIG. 11. The trenches 311 may be formed to reach a first depth D2, which is greater than approximately 0.6 μm. The trenches 311 may be formed by processes known in the art, such as photolithography patterning followed by RIE to form apertures (trenches) in the patterned areas. In the embodiment of FIG. 11, trenches 311 are etched in the substrate 30, and in particular, in the epi layer 330 of the substrate 30. The trenches 311 are etched to a first depth D2. The first depth D2 may be between approximately 0.6 μm and 2 μm.

Meanwhile, step 8300 is implemented to form at least one groove 321 in the peripheral region 320 in accordance with the predetermined pattern 350. Since the etching process of the groove 321 is substantially similar to the trenches 311, the second depth D3 of the groove 321 is substantially similar to the depth D2 of the trenches 311. However, in this process, polysilicon bump defects may be generated at the bottom of the trenches 331 or at the bottom of the groove 321 due to RIE processing.

In order to decrease the occurrence of the polysilicon bump defects, the method proceeds to step 8400 where nitrogen is incorporated into the substrate 30 at the bottom of the trenches 311 and at the bottom of the at least one groove 321 to form a nitrogenized portion 360 as shown in FIG. 12. Nitrogen incorporation may be formed by processes known in the art, such as a decoupled plasma nitridization, an ammonia anneal, or a nitrous oxide (N₂O) plasma treatment, to form the nitrogenized portion 360 at the bottom of the trenches 311 and at the bottom of the at least one groove 321.

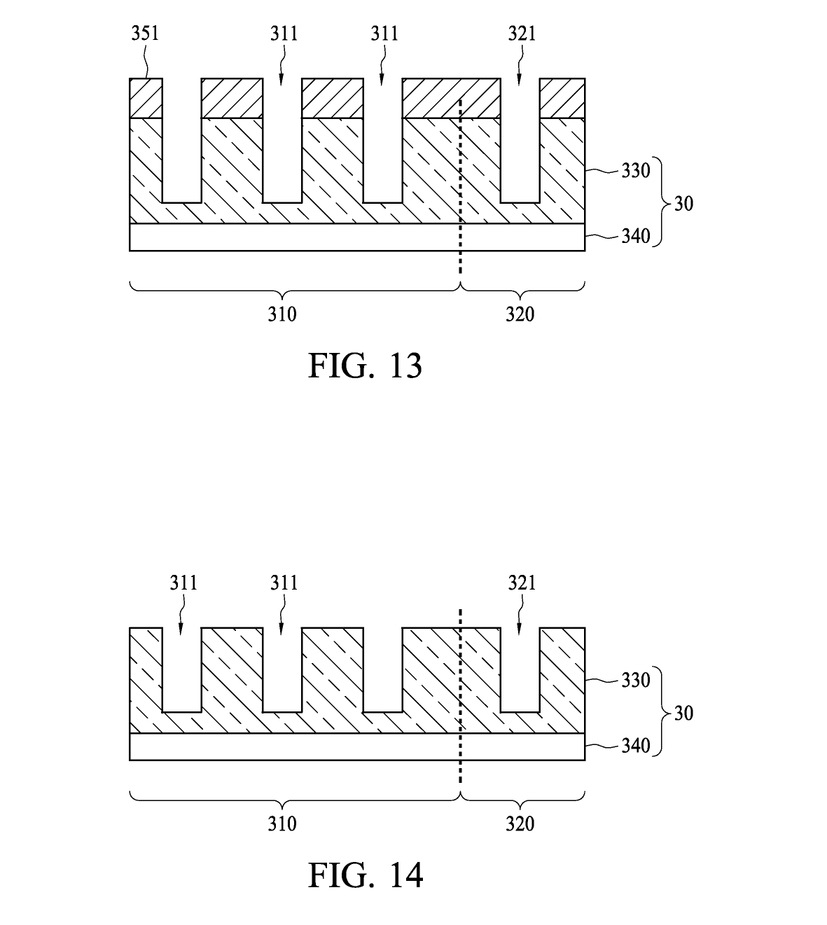

Referring to FIG. 13, the method proceeds to step 8500 where the nitrogenized portion 360 shown in FIG. 12 is removed by an etching process, which does not etch the epi layer 330 of the substrate 30. The etching process may be implemented by a phosphoric acid/peroxide mixture (Hot Phos) or hydrogen fluoride (HF) in deionized water in accordance with the desired function. Since the step has a more uniform etch front, the occurrence of the polysilicon bump defects can be reduced.

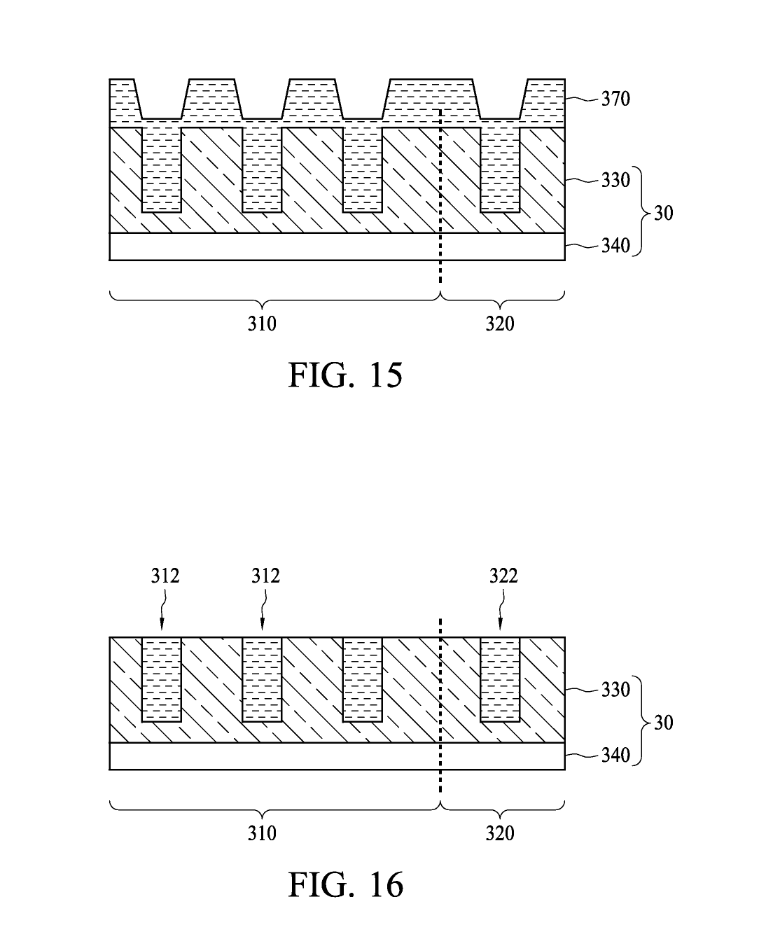

After the step 8600 is implemented to remove the photoresist masking layer 351 as shown in FIG. 14, the method proceeds to step 8700 where a layer 370 of insulating material is deposited on the substrate 30 as shown in FIG. 15. The layer 370 may be formed by depositing material using chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), sub-atmospheric CVD (SACVD), and/or other processes known in the art. In an embodiment, the insulating material is silicon oxide. In an embodiment, the oxide is deposited by either HDPCVD or SACVD. The layer 370 may fill, partially or entirely, a trench 311 formed in the pixel region 310 and a groove 321 formed in the peripheral region 320, described above in reference to steps 8200 and 8300. In the embodiment of FIG. 15, a conformal insulating layer 370 is deposited on the substrate 30. The insulating layer 370 fills the trenches 311 and the groove 321. Thus, the insulating layer 370 is now designated as isolation structures 312 of the filled trenches 311 and the isolation structure 322 of the filled groove 321 shown in FIG. 16. The method then proceeds to step 8800 where the insulating layer 370 is planarized. In an embodiment, the layer 370 is planarized by a chemical mechanical polish (CMP) process. In the example of FIG. 16, the planarized insulating layer 370 is illustrated such that the insulating material completely fills the isolation structures 312, 322 for an image sensor device and thus a substantially planar surface of the substrate 30 is provided.

In an embodiment, the image sensor device (not shown) may be a complimentary metal oxide semiconductor (CMOS) image sensor (CIS) or an active pixel sensor. In an alternative embodiment, the image sensor device may be a charge coupled device (CCD) sensor. The image sensor device may be a front-side illuminated sensor or a back-side illuminated sensor. In a back-side illuminated sensor configuration, the light to be sensed is incident on the back-side of a substrate, while the pixels are formed on the front side of the substrate. The pixels divided by isolation structures include at least one photodetector (e.g. photodiode) for recording an intensity or brightness of light. In an embodiment, the pixels include a pinned photodiode. Each of the pixels also includes at least one transistor. The pixels may include a reset transistor, a source follower transistor, a selector transistor, and/or a transfer transistor. The reset transistor may act to reset the pixels. The source follower transistor may allow a voltage associated with the pixels to be observed without removing the accumulated charge. The selector transistor may be a row-select transistor and allow a single row of pixels to be read when the selector transistor is turned on. A transfer transistor may move a charge accumulated in a photodetector of the pixels to another device and thus data is output from the pixel. A transfer transistor may allow for correlated double sampling. In one embodiment, a transfer transistor may be associated with (e.g. assigned to) a single photodiode, while a source follower, reset, and selector transistor may be associated with (e.g. shared by) a plurality of photodiodes. In a second embodiment, a transfer transistor may be associated with one photodiode, while a source follower and reset transistor may be associated with a plurality of photodiodes. In an embodiment, the pixels include four transistors each; one such image sensor element is known in the art as 4T CMOS image sensor. The 4T CMOS image sensor may include a transfer transistor, a reset transistor, a source follower transistor, and a selector transistor. In an embodiment, a transistor included in the pixel region includes a metal-oxide-semiconductor field effect transistor (MOSFET) having a gate that includes a silicide layer. The silicide layer may include a silicide, such as nickel silicide, cobalt silicide, tungsten silicide, tantalum silicide, titanium silicide, platinum silicide, erbium silicide, palladium silicide, and/or combinations thereof.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method of modifying a polysilicon layer, comprising steps of:
incorporating nitrogen into the polysilicon layer toward a first depth to form a first nitrogenized polysilicon portion; and
performing a first etching process to remove the first nitrogenized polysilicon portion, wherein the polysilicon layer is not etched by the first etching process.

2. The method according to claim 1, wherein the nitrogen incorporating step is performed by a process selected from a decoupled plasma nitridization, an ammonia anneal, and a nitrous oxide plasma treatment.

3. The method according to claim 1, wherein the first etching step is performed by using a phosphoric acid/peroxide mixture.

4. The method according to claim 1, wherein the first etching step is performed by using hydrogen fluoride in deionized water.

5. The method according to claim 1, further comprising a step of forming a photoresist masking layer on the polysilicon layer.

6. The method according to claim 5, further comprising a step of incorporating nitrogen into the photoresist masking layer and the polysilicon layer toward a second depth to form a second nitrogenized polysilicon portion.

7. The method according to claim 6, further comprising a step of removing the photoresist masking layer.

8. The method according to claim 7, further comprising a step of performing a second etching process to remove the second nitrogenized polysilicon portion, wherein the polysilicon layer is not etched by the second etching process.

9. A method of fabricating an isolation structure, comprising steps of:
providing a substrate having a pixel region and a peripheral region;
forming a photoresist masking layer with a predetermined pattern on the substrate;
forming a plurality of trenches in the pixel region in accordance with the predetermined pattern, wherein the trenches have a first depth;
forming at least one groove in the peripheral region in accordance with the predetermined pattern, wherein the at least one groove has a second depth;
incorporating nitrogen into the substrate at the bottom of the trenches and at the bottom of the at least one groove (321) to form a nitrogenized portion;
performing an etching process to remove the nitrogenized portion, wherein the substrate is not etched by the etching process;
removing the photoresist masking layer;
depositing a layer of an insulating material on the substrate; and
planarizing the layer of the insulation material.

10. The method according to claim 9, wherein the nitrogen incorporating step is performed by a process selected from a decoupled plasma nitridization, an ammonia anneal, and a nitrous oxide plasma treatment.

11. The method according to claim 9, wherein the etching step is performed by using a phosphoric acid/peroxide mixture.

12. The method according to claim 9, wherein the etching step is performed by using hydrogen fluoride in deionized water.
